(19) United States
(12) Patent Application Publication
(10) Pub. No.: US 2013/0194754 A1
(43) Pub. Date: Aug. 1, 2013

(54) TRANSMISSION LINE TRANSITION HAVING VERTICAL STRUCTURE AND SINGLE CHIP PACKAGE USING LAND GRIP ARRAY COUPLING

(71) Applicants: Dong-Yun Jung, Anyang-si (KR); Sung-Tae Choi, Hwaseong-si (KR); Young-Hwan Kim, Hwaseong-si (KR); Jung-Han Choi, Incheon (KR); Ji-Hoon Kim, Gunpo-si (KR); Jei-Young Lee, Yongin-si (KR); Dong-Hyun Lee, Anyang-si (KR)

(72) Inventors: Dong-Yun Jung, Anyang-si (KR); Sung-Tae Choi, Hwaseong-si (KR); Young-Hwan Kim, Hwaseong-si (KR); Jung-Han Choi, Incheon (KR); Ji-Hoon Kim, Gunpo-si (KR); Jei-Young Lee, Yongin-si (KR); Dong-Hyun Lee, Anyang-si (KR)

(73) Assignee: Samsung Electronics Co. Ltd., Suwon-si, Gyeonggi-do (KR)

(21) Appl. No.: 13/877,378

(22) PCT Filed: Oct. 5, 2011
(86) PCT No.: PCT/KR11/07359

§ 371 Date: Apr. 2, 2013

(30) Foreign Application Priority Data
Oct. 5, 2010 (KR) 10-2010-0096885

(51) Int. Cl. H05K 1/02; H05K 1/18

(52) U.S. Cl. CPC H05K 1/0216; H05K 1/181; H05K 1/0204
USPC 361/720; 361/773

(57) ABSTRACT

An apparatus for a single chip package using Land Grid Array (LGA) coupling is provided. The apparatus includes a multi-layer substrate, at least one integrated circuit chip, and a Printed Circuit Board (PCB). The a multi-layer substrate has at least one substrate layer, has at least one first chip region and at least one second chip region in a lowermost substrate layer, configures a transmission line transition of a vertical structure for transmitting a signal from at least one integrated circuit chip coupled in the first chip region in a coaxial shape or in a form of a Co-Planar Waveguide guide (CPW), and has an LGP coupling pad for connecting with a Printed Circuit Board (PCB) in the lowermost layer. The at least one integrated circuit chip is coupled in the first chip region and the second chip region. The PCB is connected with the multi-layer substrate using the LGA coupling via the LGA coupling pad.

### BACKGROUND OF THE INVENTION

1. Field of the Invention

The present invention relates to an apparatus for providing a single chip package minimizing Radio Frequency (RF) performance deterioration by reducing parasitic inductance occurring in the package as well as achieving low costs and miniaturization when mass-producing a product.

2. Description of the Related Art

A conventional single chip package couples a substrate of an RF band with a Printed Circuit Board (PCB) via a Ball Grid Array (BGA) technology that uses a ball having a height of about 0.6˜1 mm to form a single chip package.

This single chip package requires additional external processes such as ball forming, ball attaching, ball molding, etc. in an aspect of production. In addition, for maintaining the size of a ball and a predetermined interval, a package size increases and an attached ball may be detached, so that the single chip package has disadvantage in shipment and handling.

Also, in an RF band circuit of the single chip package, inductance generated from a ball for power supply and a ground generates performance deterioration and characteristic change such as gain reduction and frequency movement in an aspect of performance, and the ground should pass through a ball, so that the single chip package has a difficulty in radiation of heat.

### SUMMARY OF THE INVENTION

An aspect of the present invention is to address at least the above-mentioned problems and/or disadvantages and to provide at least the advantages described below. Accordingly, an aspect of the present invention is to provide an apparatus for a single chip package using Land Grid Array (LGA) coupling.

Another aspect of the present invention is to provide an apparatus for a single chip package wherein a path for power supply and a ground is short, and a signal is transmitted in a coaxial shape or in a Co-Planar Waveguide guide (CPW) shape, so that parasitic inductance is minimized and performance of an RF chip does not deteriorate and a characteristic does not change.

Still another aspect of the present invention is to provide an apparatus for an RF single chip package having excellent performance in heat radiation since a multi-layer substrate and a mainboard are directly connected via a pad.

In accordance with an aspect of the present invention, an apparatus for a single chip package using Land Grid Array (LGA) coupling is provided. The apparatus includes a multi-layer substrate having at least one substrate layer, having at least one first chip region and at least one second chip region in a lowermost substrate layer, configuring a transmission line transition of a vertical structure for transmitting a signal from at least one integrated circuit chip coupled in the first chip region in a coaxial shape or in a Co-Planar Waveguide guide (CPW) shape, and having an LGA coupling pad for connecting with a Printed Circuit Board (PCB) in the lowermost layer, the at least one integrated circuit chip coupled in the first chip region and the second chip region, and the PCB connected with the multi-layer substrate using the LGA coupling via the LGA coupling pad.

In accordance with another aspect of the present invention, an apparatus for a single chip package using Land Grid Array (LGA) coupling is provided. The apparatus includes a multi-layer substrate having at least one substrate layer, having at least one chip region in a lowermost substrate layer, configuring a transmission line transition of a vertical structure for transmitting a signal from at least one integrated circuit chip coupled in the chip region in a coaxial shape or in a Co-Planar Waveguide guide (CPW) shape, and having an LGA coupling pad for connecting with a Printed Circuit Board (PCB) in the lowermost layer, the at least one integrated circuit chip coupled in the chip region, and the PCB connected with the multi-layer substrate using the LGA coupling via the LGA coupling pad.

Other aspects, advantages and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments of the present invention will be more apparent from the following description taken in conjunction with the accompanying drawings in which:

FIG. 1 is a view illustrating a single chip package using LGA coupling according to an embodiment of the present invention;

FIG. 2 is a view illustrating a multi-layer substrate before SMT according to an embodiment of the present invention;

FIG. 3 is a view illustrating a connection structure of a mainboard and a multi-layer substrate according to an embodiment of the present invention;

FIG. 4 is a view illustrating a connection structure of a mainboard and a multi-layer substrate according to another embodiment of the present invention;

FIG. 5 is a view illustrating a connection structure of a mainboard and a multi-layer substrate according to further another embodiment of the present invention;

FIG. 6 is a view illustrating a connection structure of a mainboard and a multi-layer substrate according to still another embodiment of the present invention;

FIG. 7 is a view illustrating a connection structure of a mainboard and a multi-layer substrate according to yet another embodiment of the present invention;

FIG. 8 is a view illustrating a connection structure of a mainboard and a multi-layer substrate according to yet still another embodiment of the present invention;

FIG. 9 is a view illustrating a connection structure of a mainboard and a multi-layer substrate according to yet further another embodiment of the present invention;

FIG. 10 is a view illustrating a connection structure of a mainboard and a multi-layer substrate according to still yet another embodiment of the present invention;

FIG. 11 is a view illustrating a connection structure of a mainboard and a multi-layer substrate according to still yet further another embodiment of the present invention;

FIG. 12 is a view illustrating a connection structure of a mainboard and a multi-layer substrate according to yet still another embodiment of the present invention;

FIG. 13 is a view illustrating a connection structure of a mainboard and a multi-layer substrate according to yet still further another embodiment of the present invention; and

FIG. 14 is a view illustrating a connection structure of a mainboard and a multi-layer substrate according to yet another embodiment of the present invention.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

Exemplary embodiments of the present invention provide an apparatus for a single chip package using LGA coupling.

The present invention provides an apparatus for a single chip package using LGA coupling wherein the package has a short path for power supply and a ground, and transmits a signal in a coaxial shape or in a Co-Planar Waveguide guide (CPW) shape, so that parasitic inductance is minimized and performance of an RF chip does not deteriorate and a characteristic does not change as well as it enables low costs and miniaturization when mass-producing a product.

Particularly, the present invention is very useful for a millimeter wave band and may be used for implementing a system for a multi-frequency application in a system-on-package (SoP) such as a case where a millimeter wave band system is integrated in an integrated system of 2/5 GHz bands.

An apparatus of the present invention couples a multi-layer substrate with a mainboard using a coupling pad for LGA coupling, and may mount one or a plurality of integrated circuit chips thereon.

In the present invention, a multi-layer substrate mounting an RF (millimeter wave) band antenna or transition between an integrated circuit chip and an antenna therein has an interconnection contact pad for LGA coupling with a mainboard, so that the multi-layer substrate may be connected via simple soldering without an additional process.

In the present invention, a chip is connected with the multi-layer substrate via a flip-chip bump or a wire, and in case of an RF chip, GND vias are positioned in the neighborhood of a signal line bump, so that they play a role of a low loss transmission line such as a coaxial shape or a Co-Planar Waveguide guide (CPW).

The mainboard forms a cavity to provide a concave portion so that a chip attached on the multi-layer substrate may not bump into the mainboard. In addition, the mainboard may include an input end connected with a low frequency band antenna. In addition, the mainboard is used in the same meaning as a PCB in the present invention.

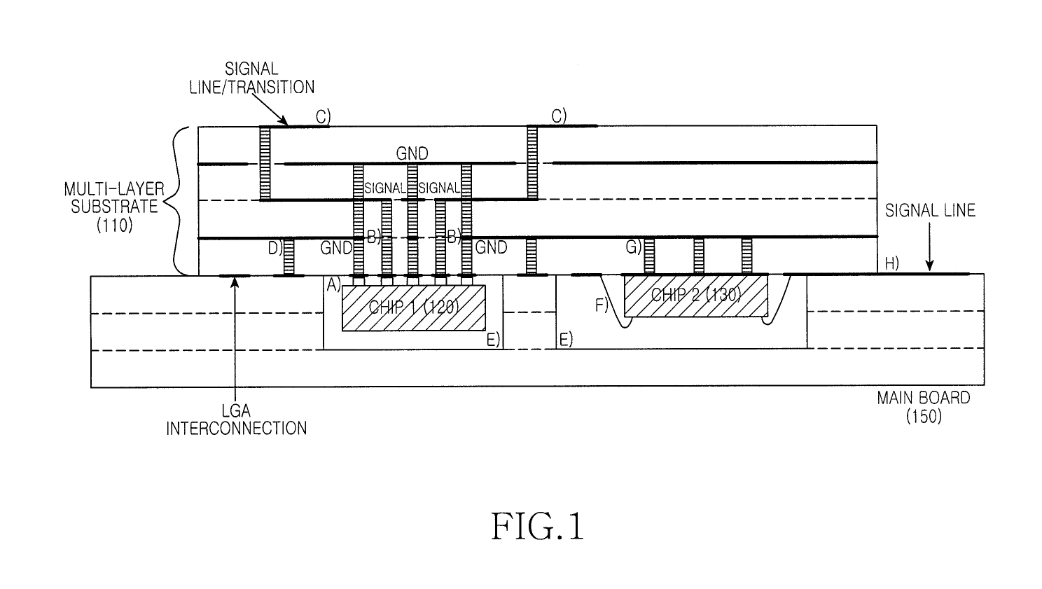

FIG. 1 illustrates a single chip package using LGA coupling according to an embodiment of the present invention.

Referring to FIG. 1, a signal, GND, and power of a chip 1 120 may be connected with a multi-layer substrate 110 via flip-chip bonding (step A).

An RF signal is enclosed by two or more GND vias to maintain a coaxial cable shape or a CPW shape (step B).

A transition that can connect with an antenna or an external antenna is positioned in the uppermost layer of the multi-layer substrate 110 (step C).

In the multi-layer structure of the multi-layer substrate 110, power, GND, digital/IF signal, etc. may be connected with the mainboard 150 (step D).

Chips 1, 2 120 and 130 are positioned in cavities in the mainboard 150 (step E).

Connection ends such as signal, GND, power of the chip 2 130 may be connected with the multi-layer substrate 110 via wire bonding (step F).

The chip 2 130 may be connected with GND mounted inside the multi-layer substrate 110 through a via of the multi-layer substrate 110 (step G).

Ends such as power, GND, digital/IF signal, etc. of the chip 2 130 may be connected with the mainboard 150 (step H).

In the above single chip structure, a structure where the chip 1 120 and the multi-layer structure 110 are connected may be more suitably used for an RF region. In addition, a structure where the chip 2 130 and the multi-layer structure 110 are connected may be used for a low frequency region.

This is because the structure where the chip 1 120 and the multi-layer structure 110 are connected shows low performance deterioration for the RF region and even the low frequency region, and the structure where the chip 2 130 and the multi-layer structure 110 are connected shows relatively high performance deterioration for the RF region but shows low performance deterioration for the low frequency region.

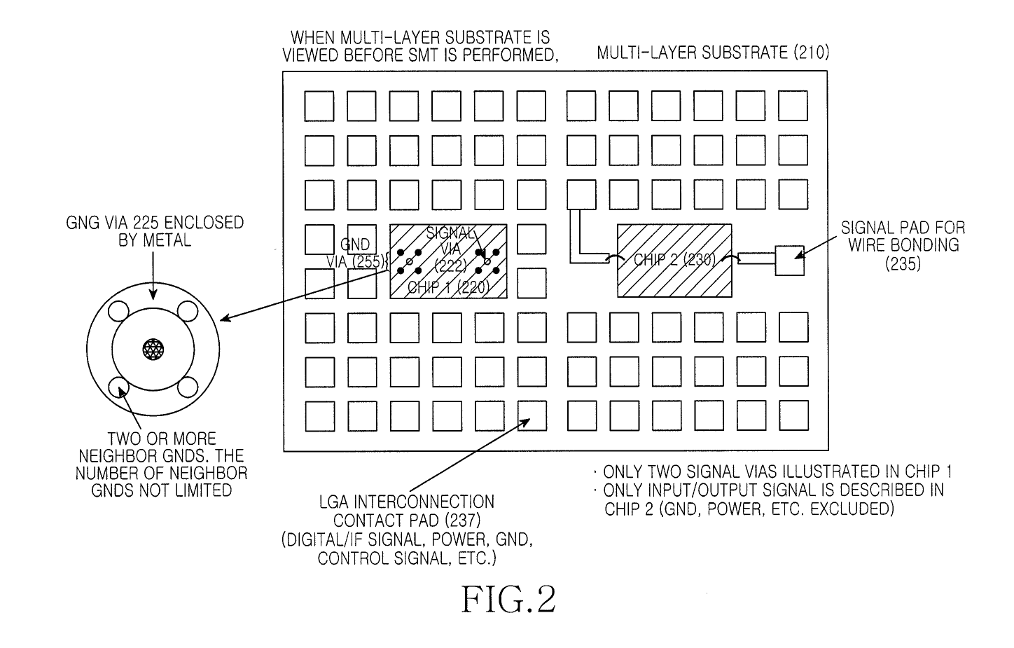

FIG. 2 illustrates a multi-layer substrate before SMT according to an embodiment of the present invention.

Referring to FIG. 2, a multi-layer substrate 210 before SMT is illustrated. The multi-layer substrate 210 includes a chip 1 220 and a chip 2 230 as an embodiment, but the number of chips is not limited in implementation.

As described above, the chip 2 230 may be connected with a signal pad 235 via the multi-layer substrate 210 and wire bonding.

In the chip 1 220, as an embodiment, two signal vias 227 are illustrated. The signal via 227 is enclosed by GNG vias 225, and the GNG vias 225 are enclosed by metal.

The number of GND vias 225 enclosing the signal via 227 is two or more per one signal via, and a maximum number of GND vias is not limited. The signal via 227 and the GND via 225 have a coaxial shape or a CPW shape, and have an advantage that performance deterioration is low in the RF region.

For connection using LGA coupling, an LGA interconnection contact pad 237 may be used for digital/IF signal, power, GND, control signal transmission of the chips 1, 2 220 and 230, and as described above, it may be used for coupling with the mainboard.

In an embodiment which will be described below, how the chip 2 is connected with the multi-layer substrate or the mainboard between the multi-layer substrate and the mainboard, and how a cavity is formed between the multi-layer substrate and the mainboard, and whether a heat sink is attached to the mainboard are described.

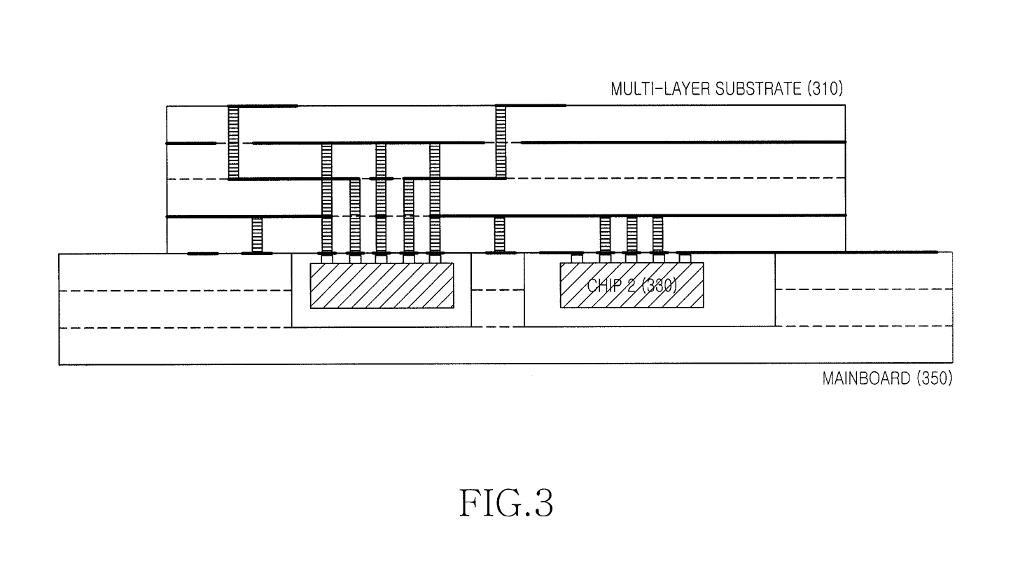

FIG. 3 is a view illustrating a connection structure of a mainboard and a multi-layer substrate according to an embodiment of the present invention.

Referring to FIG. 3, a chip 2 330 is connected to the multi-layer substrate 310 using flip-chip bonding between the multi-layer substrate 310 and the mainboard 350. In FIG. 3, a cavity is positioned in the mainboard 350.

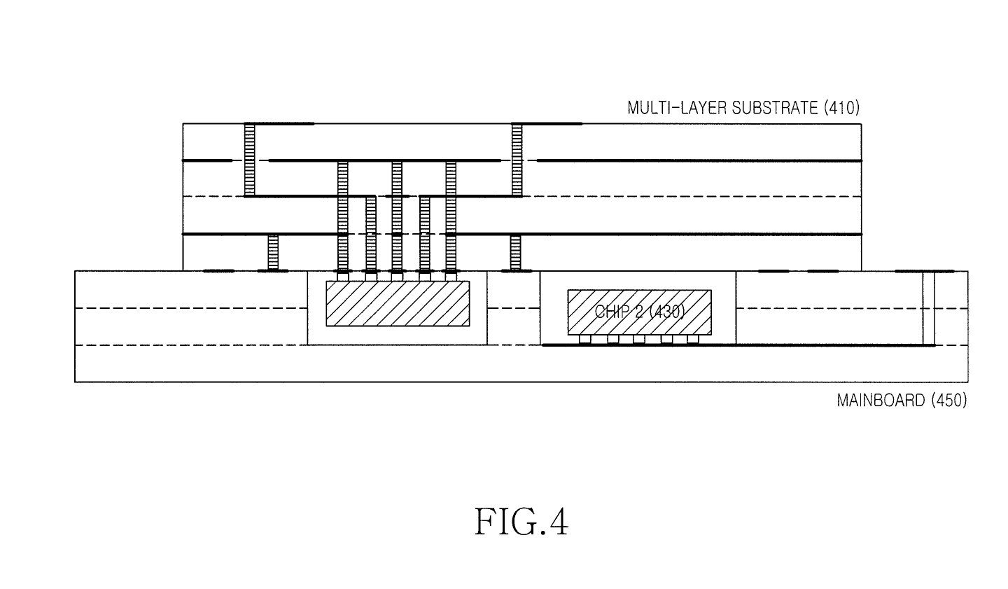

FIG. 4 is a view illustrating a connection structure of a mainboard and a multi-layer substrate according to another embodiment of the present invention.

Referring to FIG. 4, a chip 2 430 is connected to the mainboard 450 using flip-chip bonding between the multi-layer substrate 410 and the mainboard 450. In this case, a cavity is positioned in the mainboard.

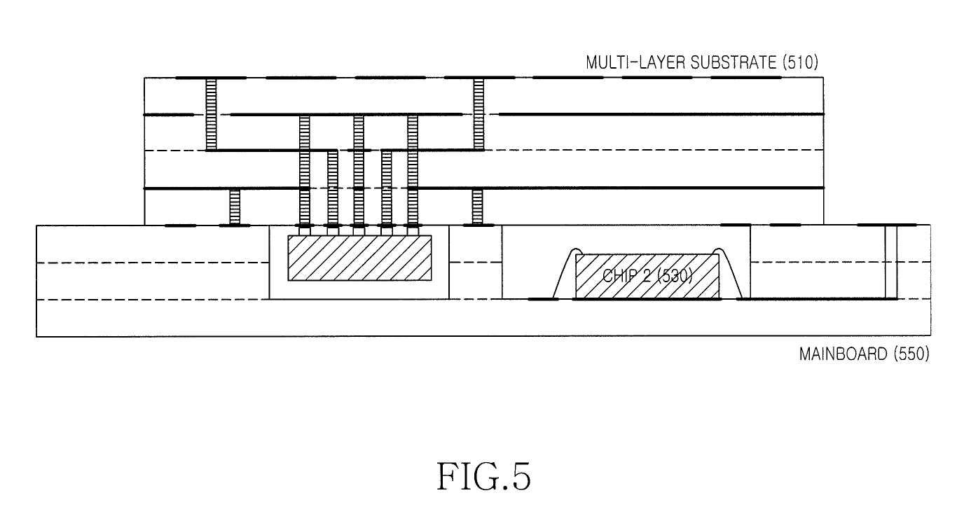

FIG. 5 is a view illustrating a connection structure of a mainboard and a multi-layer substrate according to further another embodiment of the present invention.

Referring to FIG. 5, a chip 2 530 is connected to the mainboard 550 using wire bonding between the multi-layer substrate 510 and the mainboard 550. In this case, a cavity is positioned in the mainboard 550.

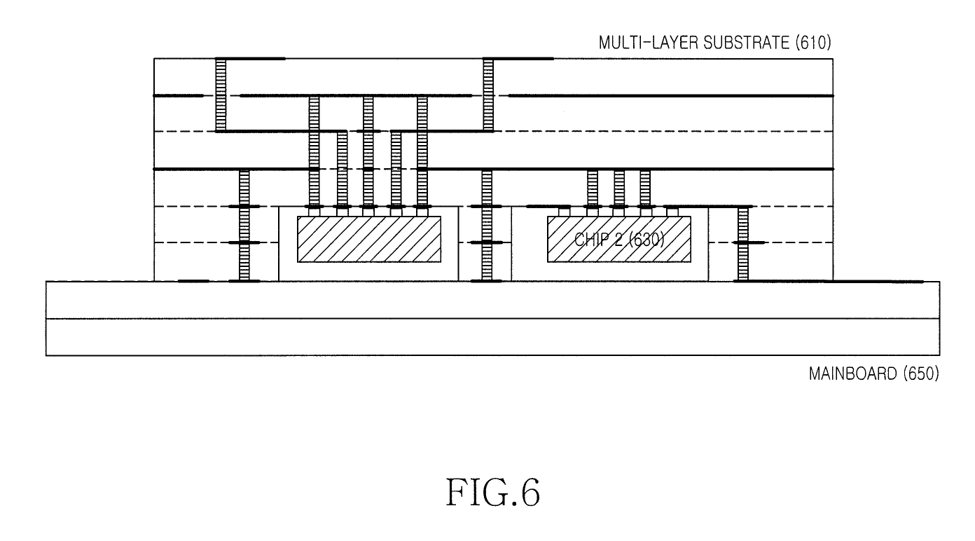

FIG. 6 is a view illustrating a connection structure of a mainboard and a multi-layer substrate according to still another embodiment of the present invention.

Referring to FIG. 6, a chip 2 630 is connected to the multi-layer substrate 610 using flip-chip bonding between the multi-layer substrate and the mainboard 650. In this case, a cavity is positioned in the multi-layer substrate 610.

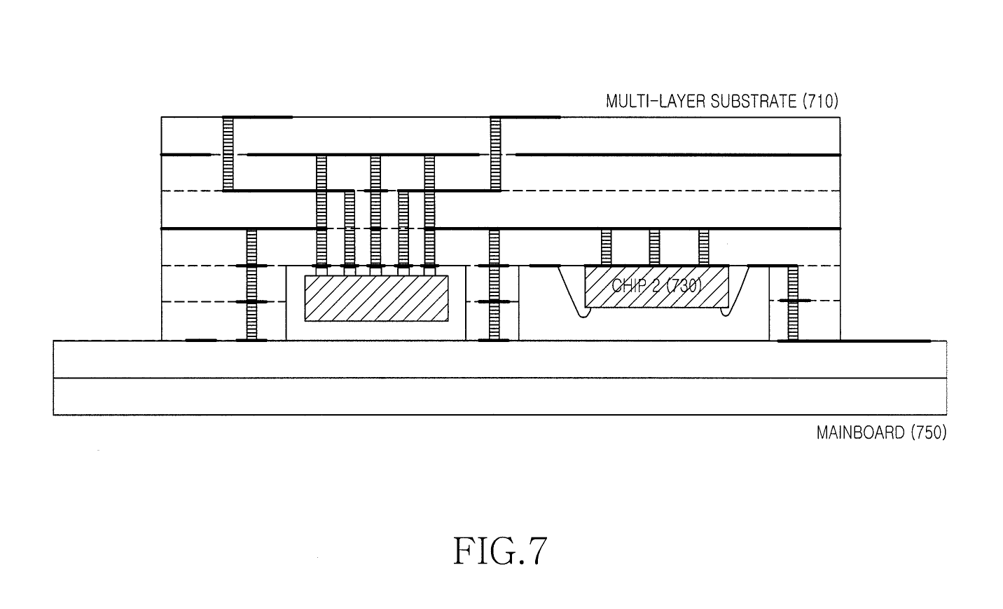

FIG. 7 is a view illustrating a connection structure of a mainboard and a multi-layer substrate according to yet another embodiment of the present invention.

Referring to FIG. 7, a chip 2 730 is connected to the multi-layer substrate 710 using wire bonding between the multi-layer substrate 710 and the mainboard 750. In this case, a cavity is positioned in the multi-layer substrate 710.

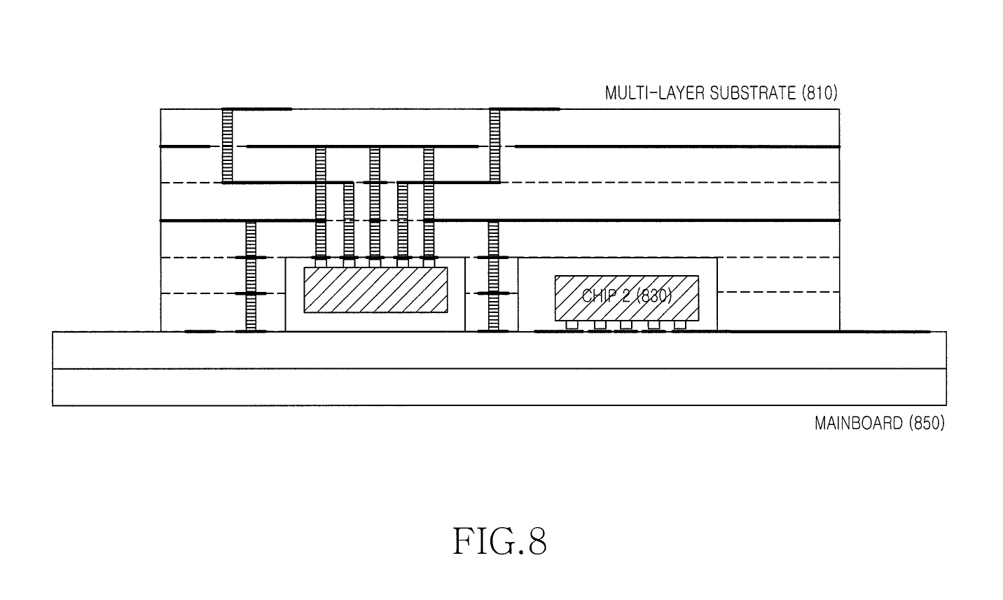

FIG. 8 is a view illustrating a connection structure of a mainboard and a multi-layer substrate according to yet still another embodiment of the present invention.

Referring to FIG. 8, a chip 2 830 is connected to the mainboard 850 using flip-chip bonding between the multi-layer substrate 810 and the mainboard 850. In this case, a cavity is positioned in the multi-layer substrate 810.

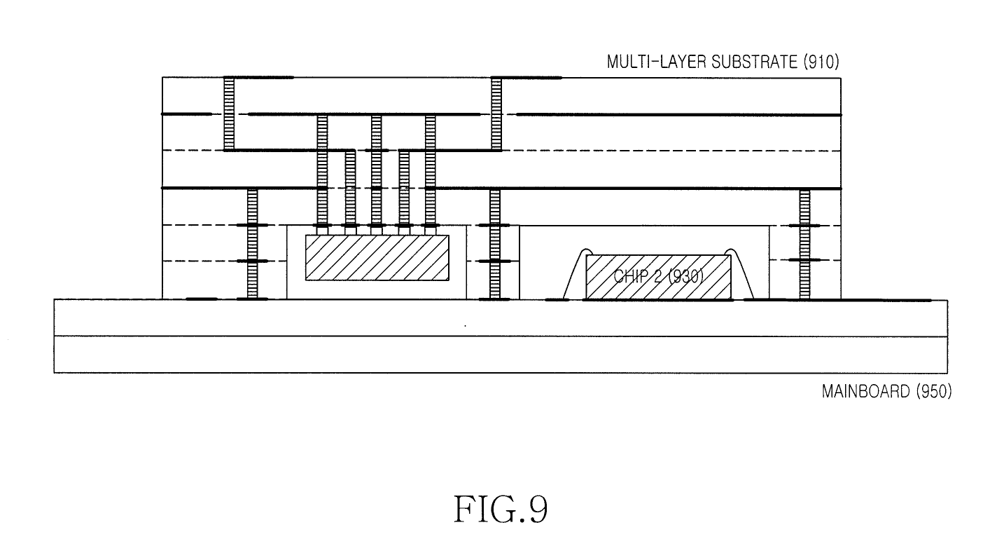

FIG. 9 is a view illustrating a connection structure of a mainboard and a multi-layer substrate according to yet further another embodiment of the present invention.

Referring to FIG. 9, a chip 2 930 is connected to the mainboard 950 using wire bonding between the multi-layer substrate 910 and the mainboard 950. In this case, a cavity is positioned in the multi-layer substrate 910.

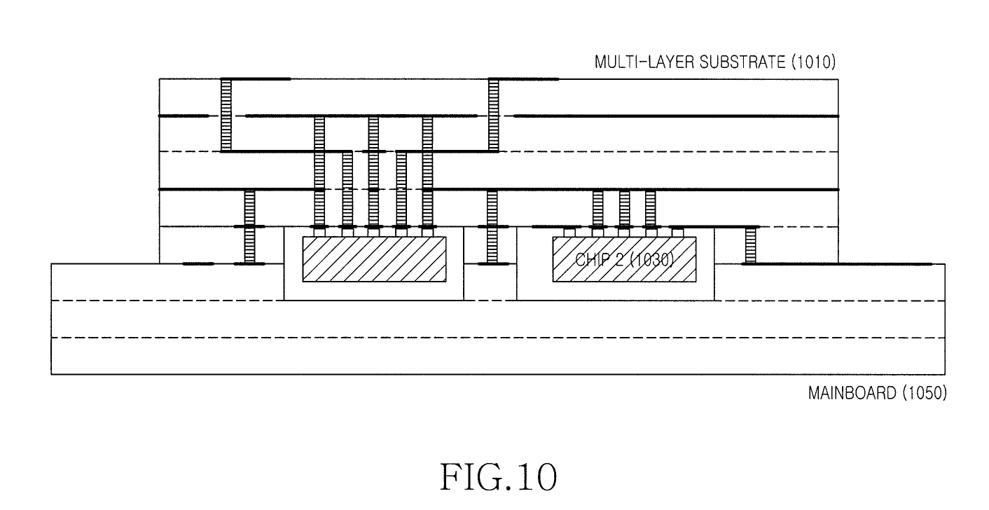

FIG. 10 is a view illustrating a connection structure of a mainboard and a multi-layer substrate according to still yet another embodiment of the present invention.

Referring to FIG. 10, a chip 2 1030 is connected to the multi-layer substrate 1010 using flip-chip bonding between the multi-layer substrate 1010 and the mainboard 1050. In this case, a cavity is positioned in the multi-layer substrate 1010 and the mainboard 1050 together.

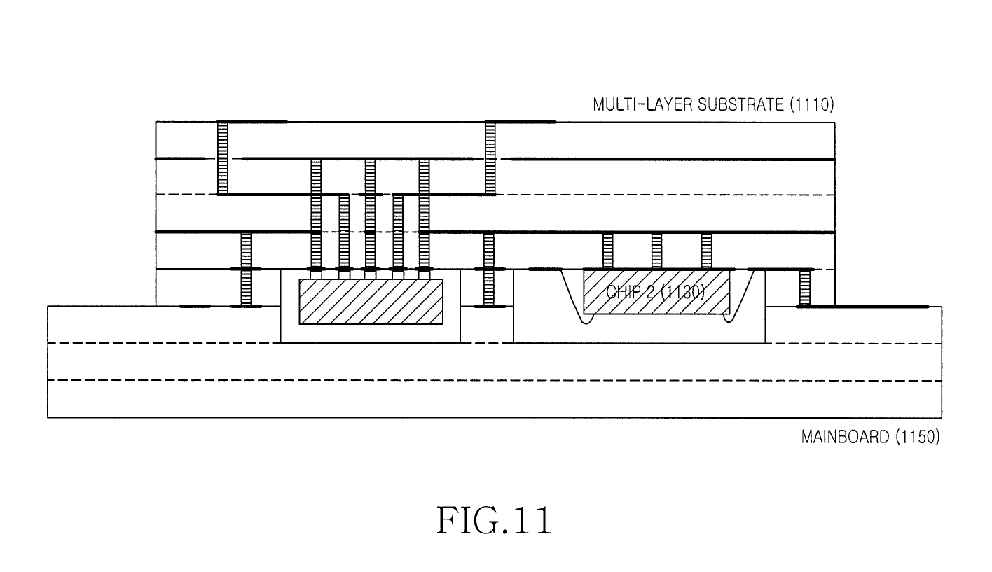

FIG. 11 is a view illustrating a connection structure of a mainboard and a multi-layer substrate according to still yet further another embodiment of the present invention.

Referring to FIG. 11, a chip 2 1130 is connected to the multi-layer substrate 1110 using wire bonding between the multi-layer substrate 1110 and the mainboard 1150. In this case, a cavity is positioned in the multi-layer substrate 1110 and the mainboard 1150 together.

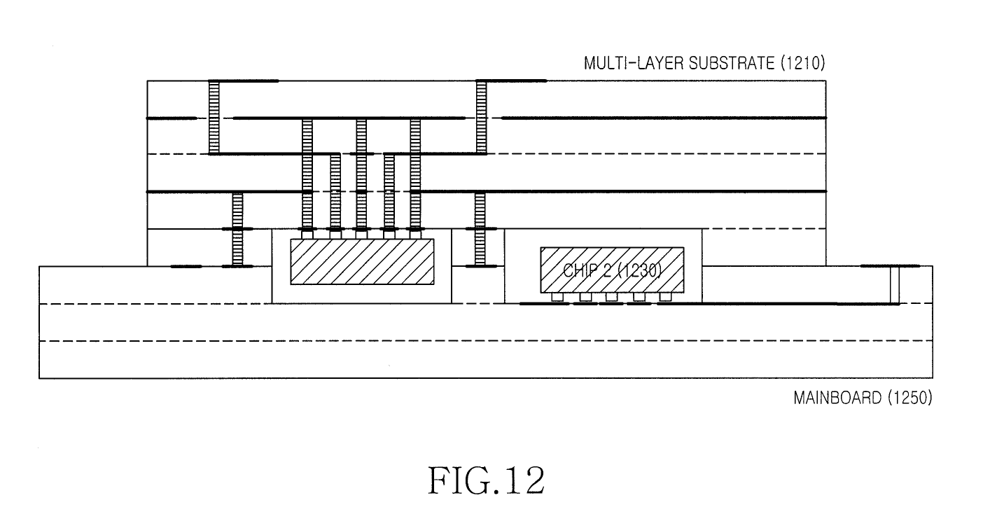

FIG. 12 is a view illustrating a connection structure of a mainboard and a multi-layer substrate according to yet still another embodiment of the present invention.

Referring to FIG. 12, a chip 2 1230 is connected to the mainboard 1250 using flip-chip bonding between the multi-layer substrate 1210 and the mainboard 1250. In this case, a cavity is positioned in the multi-layer substrate 1210 and the mainboard 1250 together.

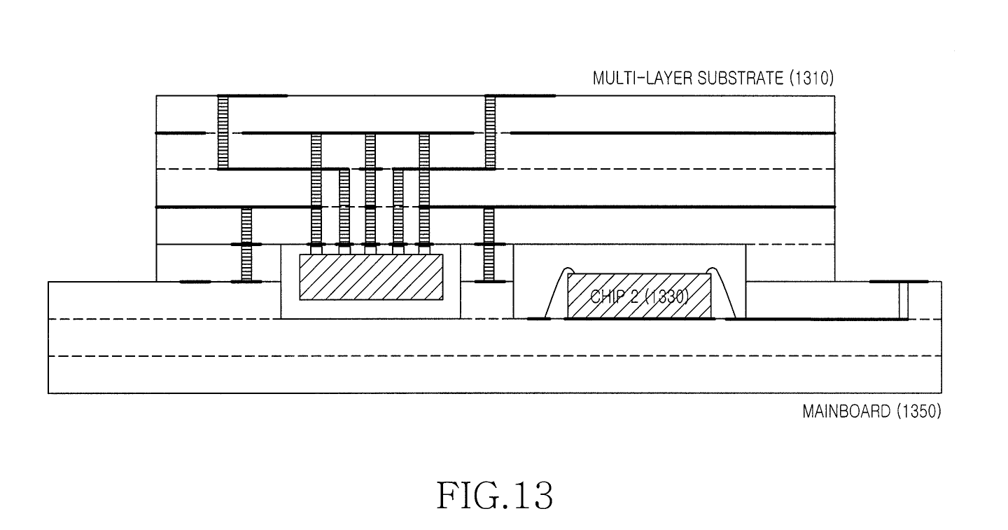

FIG. 13 is a view illustrating a connection structure of a mainboard and a multi-layer substrate according to yet still further another embodiment of the present invention.

Referring to FIG. 13, a chip 2 1330 is connected to the mainboard 1350 using wire bonding between the multi-layer substrate 1310 and the mainboard 1350. In this case, a cavity is positioned in the multi-layer substrate 1310 and the mainboard 1350 together.

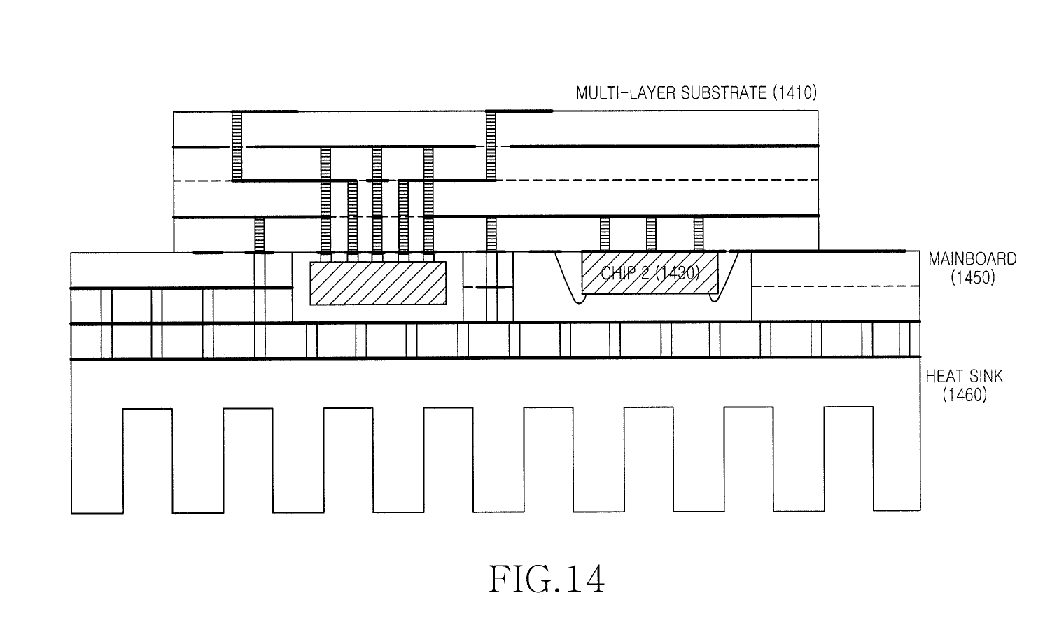

FIG. 14 is a view illustrating a connection structure of a mainboard and a multi-layer substrate according to yet another embodiment of the present invention.

Referring to FIG. 14, a chip 2 1430 is connected to the multi-layer substrate 1410 using wire bonding between the multi-layer substrate 1410 and the mainboard 1450. In this case, a cavity is positioned in the mainboard 1450.

In addition, a heat sink 1460 is attached to the mainboard 1450 to help heat emission of the mainboard 1450. The heat sink 1460 may be attached to all mainboards of FIGS. 3 to 13 to help heat emission.

Since the present invention does not require an additional process, it is advantageous in cost reduction, mass production, and miniaturization. Also, according to the present invention, since a power and GND path is short, parasitic inductance is small, so that an RF system performance is stable and it has an advantage in heat radiation and so the present invention is very advantageously applied to a portable terminal. Also, small-sized single integrated packaging of a millimeter wave band system or an integrated system of the millimeter wave band and a 2/5 GHz band is possible.

Although the invention has been shown and described with reference to certain exemplary embodiments thereof, it will be understood by those skilled in the art that various changes in form and details may be made therein without departing from the spirit and scope of the invention as defined by the appended claims and their equivalents. Therefore, the scope of the present invention should not be limited to the above-described embodiments but should be determined by not only the appended claims but also the equivalents thereof.

What is claimed is:

1. An apparatus for a single chip package using Land Grid Array (LGA) coupling, the apparatus comprising:
a multi-layer substrate having at least one substrate layer, having at least one first chip region and at least one second chip region in a lowermost substrate layer, configuring a transmission line transition of a vertical structure for transmitting a signal from at least one integrated circuit chip coupled in the first chip region in a coaxial shape or in a Co-Planar Waveguide guide (CPW) shape, and having an LGA coupling pad for connecting with a Printed Circuit Board (PCB) in the lowermost layer;
the at least one integrated circuit chip coupled in the first chip region and the second chip region; and
the PCB connected with the multi-layer substrate using the LGA coupling via the LGA coupling pad.

2. The apparatus of claim 1, wherein the multi-layer substrate comprises at least one antenna for radiating a signal transmitted in the coaxial shape or in the CPW shape in at least one layer of the multi-layer substrate, or
the multi-layer substrate comprises at least one antenna coupling pad for connection with an external antenna for radiating a signal transmitted in the coaxial shape or in the CPW shape in an uppermost layer of the substrate.

3. The apparatus of claim 1, wherein the at least one integrated circuit chip coupled in the first chip region is coupled with the multi-layer substrate via flip-chip bonding.

4. The apparatus of claim 1, wherein the coaxial shape or the CPW shape comprises configuration where at least two ground vias exist around each of at least one signal via for connecting the multi-layer substrate with the at least one integrated circuit chip coupled in the first chip region.

5. The apparatus of claim 1, further comprising a heat sink attached to the PCB, for emitting heat.

6. The apparatus of claim 1, wherein the at least one integrated circuit chip coupled in the second chip region is coupled with the multi-layer substrate via flip-chip bonding or wire bonding.

7. The apparatus of claim 1, wherein the at least one integrated circuit chip for the second chip region is coupled to the PCB via flip-chip bonding or wire bonding.

8. The apparatus of claim 1, wherein a cavity for the at least one integrated circuit chip coupled to the first chip region and the second chip region is formed in at least one of the multi-layer substrate and the PCB.

9. The apparatus of claim 1, wherein a signal, a ground, and power between the multi-layer substrate and the PCB are connected via LGA coupling.

10. An apparatus for a single chip package using Land Grid Array (LGA) coupling, the apparatus comprising:
a multi-layer substrate having at least one substrate layer, having at least one chip region in a lowermost substrate layer, configuring a transmission line transition of a vertical structure for transmitting a signal from at least one integrated circuit chip coupled in the chip region in a coaxial shape or in a Co-Planar Waveguide guide (CPW) shape, and having an LGA coupling pad for connecting with a Printed Circuit Board (PCB) in the lowermost layer;
the at least one integrated circuit chip coupled in the chip region; and
the PCB connected with the multi-layer substrate using the LGA coupling via the LGA coupling pad.

11. The apparatus of claim 10, wherein the multi-layer substrate comprises at least one antenna for radiating a signal transmitted in the coaxial shape or in the form of the CPW in at least one layer of the multi-layer substrate, or
the multi-layer substrate comprises at least one antenna coupling pad for connection with an external antenna for radiating a signal transmitted in the coaxial shape or in the form of the CPW in an uppermost layer of the substrate.

12. The apparatus of claim 10, wherein the at least one integrated circuit chip coupled in the chip region is coupled with the multi-layer substrate via flip-chip bonding, and a signal, a ground, and power between the multi-layer substrate and the PCB are connected via LGA coupling.

13. The apparatus of claim 10, wherein the coaxial shape or the CPW shape comprises configuration where at least two ground vias exist around each of at least one signal via for connecting the multi-layer substrate with the at least one integrated circuit chip coupled in the chip region.

14. The apparatus of claim 10, further comprising a heat sink attached to the PCB, for emitting heat.

15. The apparatus of claim 10, wherein a cavity for the at least one integrated circuit chip coupled in the chip region is formed in at least one of the multi-layer substrate and the PCB.
